(19) United States
(12) Patent Application Publication
(10) Pub. No.: US 2026/0101762 A1
(43) Pub. Date: Apr. 9, 2026

(54) BACK-TO-BACK STACKED SILICON-BASED CAPACITORS IN A PACKAGE SUBSTRATE FOR A SYSTEM-ON-CHIP

(71) Applicant: Microsoft Technology Licensing, LLC, Redmond, WA (US)

(72) Inventors: Martin Alejandro RODRIGUEZ BERROTERAN, Morrisville, NC (US); Jon Thomas WOODYARD, Livermore, CA (US); Hengzhi LUO, Morrisville, NC (US); Priyatharshan PATHMANATHAN, Wake Forest, NC (US)

(21) Appl. No.: 18/909,673

(22) Filed: Oct. 8, 2024

(51) Int. Cl. H01L 23/64; H01L 21/48; H01L 23/00; H01L 23/538; H01L 25/16

(52) U.S. Cl. CPC H10W 44/601; H10W 70/05; H10W 70/611; H10W 70/685; H10W 90/00; H10W 72/20

(57) ABSTRACT

Back-to-back stacked silicon-based capacitors in a package substrate for a system-on-chip (SoC) and methods of forming the same are described. An example system includes a package substrate comprising a core layer including plated-through holes. The system further includes at least one die mounted on top of the package substrate, where the at least one die includes at least one voltage domain. The system further includes a set of back-to-back stacked silicon-based capacitors formed within the core layer of the package substrate. The set of back-to-back stacked silicon-based capacitors may be formed in slots within the core layer in regions excluding the plated-through holes. A subset of the set of back-to-back stacked silicon-based capacitors may be coupled to components within the at least one voltage domain to manage an impedance associated with the at least one voltage domain.

### BACKGROUND

A system-on-chip (SoC), or a similar system, can experience rapid changes in power consumption due to the dynamic nature of the workloads that may be handled by the SoC. These fluctuations in activity result in variations in the voltage supplied to the integrated circuit (IC) included within the SoC, which, if significant, can lead to degradation in the performance and power efficiency of the SoC. In certain circumstances, such variations in the voltage can even cause functional errors.

Power delivery networks (PDNs) are designed to minimize these voltage variations through a combination of passive components (such as capacitors) and control loops (e.g., the voltage regulator modules). Some systems may utilize capacitors positioned on the backside of the package (land-side capacitors) and/or capacitors placed next to the die on the package surface layer (die-side capacitors).

However, with the increasing power demands and faster ramp times of next-generation SoCs, capacitors need to be electrically closer than ever to the die (e.g., the SoC die), while still offering sufficient capacitance density. One hurdle in implementing such closer capacitors is the thickness disparity between the component (e.g., silicon capacitors≤800 um) and the package core of large packages (e.g., laminate>1 mm). This disparity requires package manufacturers to back-fill the core with a plugging resin to bring the thicknesses to parity prior to embedding any components in the core. Given that the silicon-based capacitors have a lower capacitance density compared to the multilayer ceramic chip capacitors (MLCCs), there is a need for core substrates with a higher effective density of capacitors.

### SUMMARY

In one example, the present disclosure relates to a system comprising a package substrate comprising a core layer including plated-through holes. The system may further include at least one die mounted on top of the package substrate, where the at least one die includes at least one voltage domain.

The system may further include a set of back-to-back stacked silicon-based capacitors formed within the core layer of the package substrate. The set of back-to-back stacked silicon-based capacitors may be formed in slots within the core layer in regions excluding the plated-through holes. A subset of the set of back-to-back stacked silicon-based capacitors may be coupled to components within the at least one voltage domain to manage an impedance associated with the at least one voltage domain.

In another example, the present disclosure relates to a system comprising a package substrate comprising a core layer including plated-through holes. The system may further include at least one die mounted on top of the package substrate, where the at least one die includes a first voltage domain and a second voltage domain, and where during operation of the system the first voltage domain requires faster changes in power than the second voltage domain.

The system may further include a set of back-to-back stacked silicon-based capacitors formed within the core layer of the package substrate. The set of back-to-back stacked silicon-based capacitors may be formed in slots within the core layer in regions excluding the plated-through holes. The set of back-to-back stacked silicon-based capacitors may comprise a first set of silicon-based capacitors stacked on a respective second set of silicon-based capacitors. The first set of the silicon-based capacitors are coupled to components within the first voltage domain, and where the second set of the silicon-based capacitors are coupled to components within the second voltage domain

In yet another example, the present disclosure relates to a method comprising providing a package substrate comprising a core layer including plated-through holes. The method may further include mounting at least one die on top of the package substrate, where the at least die includes at least one voltage domain.

The method may further include providing a set of back-to-back stacked silicon-based capacitors formed within the core layer of the package substrate, where the set of back-to-back stacked silicon-based capacitors are formed in slots within the core layer in regions excluding the plated-through holes, and where a subset of the set of back-to-back stacked silicon-based capacitors are coupled to components within the at least one voltage domain to manage an impedance associated with the at least one voltage domain.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIG. 1 shows a view of a system including a package substrate comprising back-to-back stacked silicon-based capacitors in accordance with one example;

FIG. 2 shows an expanded view of a portion of the system of FIG. 1 in accordance with one example;

FIG. 3 shows a view of two steps of the manufacturing process for forming back-to-back stacked silicon-based capacitors as part of the core layer of FIG. 1 in accordance with one example;

FIG. 4 shows a view of the next steps of the manufacturing process for forming back-to-back stacked silicon-based capacitors as part of the core layer of FIG. 1 in accordance with one example;

FIG. 5 shows a view of the next steps of the manufacturing process for forming back-to-back stacked silicon-based capacitors as part of the core layer of FIG. 1 in accordance with one example;

FIG. 6 shows curves comparing the performance of power distribution networks (PDNs) with different capacitor designs included in a system;

FIG. 7 shows a larger number of plated-through holes formed as part of a package substrate with back-to-back stacked silicon-based capacitors relative to the number of plated-through holes formed as part of a package substrate with non-stacked single capacitors; and

FIG. 8 shows a flow chart of a method for providing a package substrate comprising back-to-back stacked silicon-based capacitors in accordance with one example.

### DETAILED DESCRIPTION

Examples described in this disclosure relate to back-to-back stacked silicon-based capacitors in a package substrate for a system-on-chip (SoC). As explained earlier, a system-on-chip (SoC), or a similar system, can experience rapid changes in power consumption due to the dynamic nature of the workloads that may be handled by the SoC. These fluctuations in activity result in variations in the voltage supplied to the integrated circuit (IC) included within the SoC, which, if significant, can lead to degradation in the performance and power efficiency of the SoC. In certain circumstances, such variations in the voltage can even cause functional errors.

Power delivery networks (PDNs) are designed to minimize these voltage variations through a combination of passive components (such as capacitors) and control loops (e.g., the voltage regulator modules). Some systems may utilize capacitors positioned on the backside of the package (land-side capacitors) and/or capacitors placed next to the die on the package surface layer (die-side capacitors).

However, with the increasing power demands and faster ramp times of next-generation SoCs, capacitors need to be electrically closer than ever to the die (e.g., the SoC die), while still offering sufficient capacitance density. One hurdle in implementing such closer capacitors is the thickness disparity between the component (e.g., silicon capacitors≤800 um) and the package core of large packages (e.g., laminate>1 mm). This disparity requires package manufacturers to back-fill the core with a plugging resin to bring the thicknesses to parity prior to embedding any components in the core. Given that the silicon-based capacitors have a lower capacitance density compared to the multilayer ceramic chip capacitors (MLCCs), there is a need for core substrates with a higher effective density of capacitors.

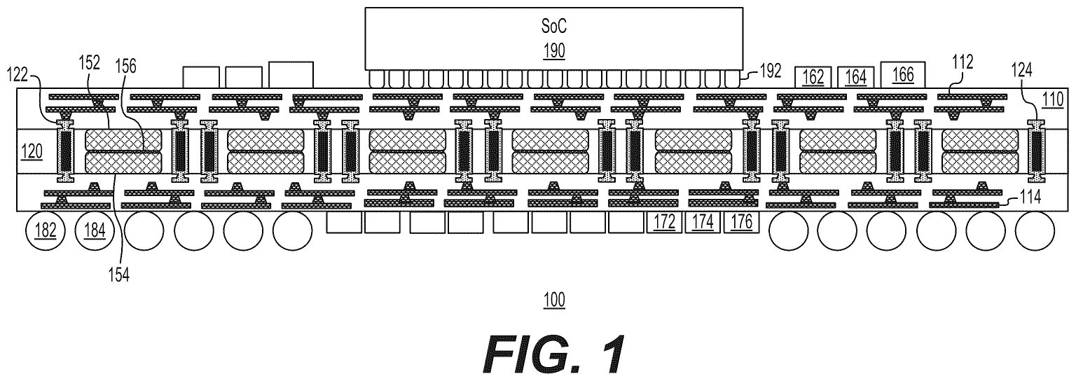

FIG. 1 shows a view of a system 100 including a package substrate 110 comprising back-to-back stacked silicon-based capacitors in accordance with one example. System 100 may be a single-die system or a multi-die system. Example topologies of multi-die systems include horizontally integrated dies (e.g., chiplets in a plane) and vertically integrated dies (e.g., 2.5D, 3D, and silicon bridge topologies). A large monolithic chip, for example a system on chip (SoC), can be split into multiple smaller dies, which are often referred to as chiplets. As used herein the term “die” includes any block of material (e.g., semiconducting material or other types of materials used in manufacturing of integrated circuits on a shared substrate) having integrated circuits, where the die can be packaged. The term “dies” includes chiplets, which are typically smaller than a die.

System 100 is shown with a system-on-chip (SoC) 190 mounted on top of package substrate 110. SoC 190 can include one or more dies. SoC 190 is mounted on top of package substrate 110 using copper pillars 192. Other types of structures can also be used to mount/attach SoC 190 to package substrate 110. In addition, other die, including memory dies, can be mounted on top of package substrate 110. System 100 is further shown with die-side multilayer ceramic chip capacitors (MLCCs) 162, 164, and 166. Die-side MLCCs 162, 164, and 166 can provide large capacitance values for smoothing and decoupling purposes. In addition, system 100 is further shown with land-side multilayer ceramic chip capacitors (MLCCs) 172, 174, and 176. Similar to the die-side capacitors, land-side MLCCs 172, 174, and 176 can provide large capacitance values for smoothing and decoupling purposes. Solder balls 182 and 184 can be attached to the bottom surface of package substrate 110 for mounting the package substrate 110 on other structures.

With continued reference to FIG. 1, in this example, package substrate 110 includes several layers, including a core layer 120. Core layer 120 can comprise laminate materials that can be used to manufacture package substrates, including printed circuit boards. In one example, such materials include fiberglass-reinforced epoxy (e.g., referred to as FR-4 or FR-5). In this example, package substrate 110 is further shown with redistribution layers 112 and 114 on both sides of the core layer 120. The redistribution layers 112 and 114 can be created using copper electroplating or other such techniques. The redistribution layers 112 and 114 allow for metal interconnection among the various components associated with package substrate 110.

Holes can be drilled into the core layer 120 to form plated-through holes (PTH), including PTH 122 and PTH 124. In this example, build-up vias are shown as part of the plated-through holes, which can act as terminals for connecting with other components or layers included in the core layer 120. FIG. 1 shows plated-through holes (similar to PTH 122 and PTH 124) formed within core layer 120 with a spacing that complies with spacing rules for such plated-through holes. Higher density of such plated-through holes allows for more optimal use of the core layer 120.

Still referring to FIG. 1, back-to-back stacked silicon-based capacitors 152 and 154 are shown. Silicon-based capacitors 152 and 154 are attached to each other using a bonding layer 156. In addition, although not shown in FIG. 1, each of silicon-based capacitors 152 and 154 can be connected to metal vias or other conductive structures. The use of back-to-back stacked silicon-based capacitors allows for formation of a higher density of plated-through holes. This is helpful because the plated-through holes can carry a larger amount of current compared with other types of packaging interconnects. Moreover, by having fewer land-side capacitors (e.g., fewer of land-side MLCCs 172, 174, and 176) one can have more room on the land-side for solder balls (e.g., solder balls 182 and 184). In addition, for power-hungry SoCs with high static power levels and large dynamic power requirements, there exists a trade-off between the DC power loss and the reliability of the SoC's performance versus the AC power loss, resulting from the capacitors and the packaging connections. The arrangement of the capacitors and the layers shown in FIG. 1 helps address the trade-off between the DC power loss and the reliability of the SoC's performance versus the AC power loss. In addition, fewer land-side capacitors are needed, opening up the land-side for additional connections (e.g., ball grid array (BGA) and land grid array (LGA) connections). Although FIG. 1 shows system 100 with a certain number of layers and components arranged in a certain manner there could be more or fewer number of layers or components, which could be arranged differently. As an example, although FIG. 1 shows SoC 190 as the die mounted on top of the package substrate 110, other types of dies may also be mounted. Such dies may comprise central processing units (CPUs), application specific integrated circuits (ASICs), graphical processing units (GPUs), field programmable gate arrays (FPGAs), microcontrollers, I/O circuits, Ethernet PHYs, or other silicon IP.

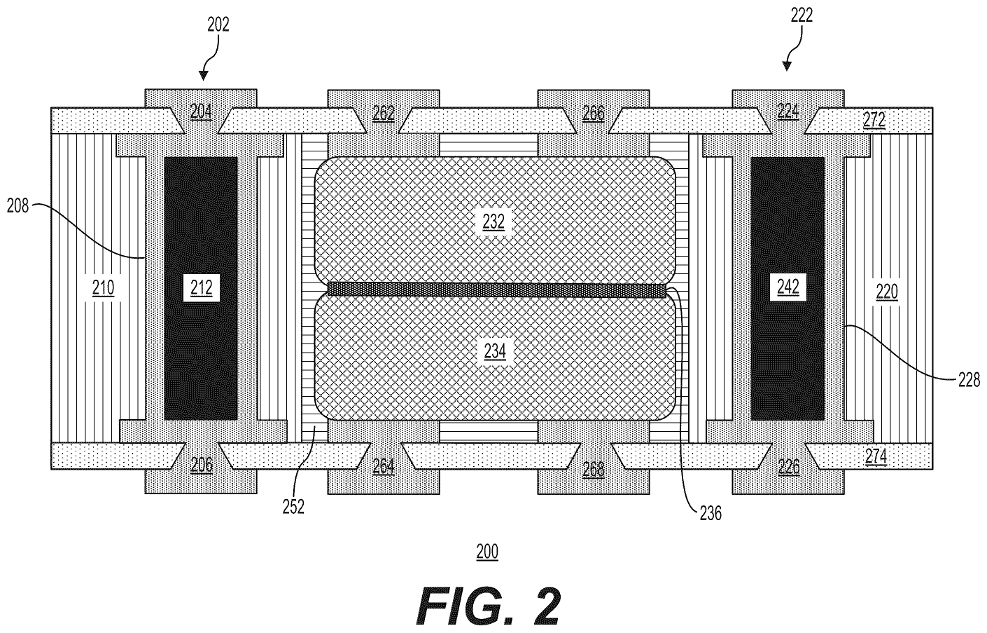

FIG. 2 shows an expanded view 200 of a portion of the system 100 of FIG. 1 in accordance with one example. Expanded view 200 shows back-to-back stacked silicon-based capacitors 232 and 234 formed within a slot separating a core layer portion 210 and another core layer portion 220. Back-to-back stacked silicon-based stacked capacitors 232 and 234 are attached to each other using a bonding layer 236. As an example, the bonding layer 236 can be a film adhesive (e.g., an acrylic adhesive or another polymer adhesive). The silicon-based capacitors can be formed via die-to-die bonding or wafer bonding techniques. As part of the wafer bonding process, two silicon wafers can be stacked on top of each other and the stacked silicon-based capacitors can be diced from the stacked wafers. In both die-to-die and wafer bonding techniques, one can apply a partially cured film (e.g., a die attach film) to one die or one wafer, then set the counterpart die or wafer on the film, and thermally cure the film. In some approaches, spin-on polymer may be used. In certain examples, the silicon-based capacitors may be hybrid bonded using active bump pads on the top and the bottom of each die for forming the back-to-back stacked silicon-based capacitors 232 and 234. In such hybrid bonded silicon-based capacitors, the bonding material may change into silicon-dioxide, which is fused with copper interconnects. Through-silicon vias may be used to reveal the top and the bottom of the wafer-to-wafer stack.

In this example, the height of the back-to-back stacked silicon-based capacitors 232 and 234 is selected to be about the same as a width of core layer (e.g., core layer 120 of FIG. 1). Thus, the combined width of each of silicon-based capacitor and silicon-based capacitor is selected to be about the same as the width of the core layer. The width of the core layer is the same as the thickness of the laminate material being used to form the core layer.

In addition, silicon-based capacitor 232 is coupled to build-up vias 262 and 266 and silicon-based capacitor 234 is coupled to build-up vias 264 and 268. Build-up vias 262 and 266 are formed after build-up layer 272 has been formed. Similarly, build-up vias 264 and 268 are formed after build-up layer 274 has been formed. Build-up vias 262 and 266 (alone or in combination) can act as a terminal for the silicon-based capacitor 232 and build-up vias 264 and 266 (alone or in combination) can act as a terminal for the silicon-based capacitor 234. In one example, build-up layers 272 and 274 may be formed using Ajinmoto build film (ABF) or similar materials. Plugging resin 252 is formed to plug any space remaining after the formation of the back-to-back silicon-based capacitors 232 and 234.

With continued reference to FIG. 2, expanded view 200 of a portion system 100 of FIG. 1 further shows two plated-through holes, including PTH 202 and 222. PTH 202 is formed by drilling a hole in core layer material 210. PTH 202 includes via-fill material 212. PTH 202 further includes copper (or another type of metal or alloy) plating 208, surrounding via-fill material 212. Built-up vias 204 and 206 are formed on either side of copper plating 208 associated with PTH 202, as needed. PTH 222 is formed by drilling a hole in core layer material 220. PTH 222 includes via-fill material 242. PTH 222 further includes copper (or another type of metal or alloy) plating 228, surrounding via-fill material 242. Built-up vias 224 and 226 are formed on either side of copper plating 228 associated with PTH 222, as needed. Advantageously, by forming the back-to-back stacked silicon-based capacitors 232 and 234, more such capacitors can be included as part of the core layer. As an example, in an inferior implementation, there may only be one silicon-based capacitor and the remaining portion below the silicon-based capacitor may be filled using a plugging resin or a similar such material. Although FIG. 2 shows a certain number of layers and components arranged in a certain manner there could be more or fewer number of layers or components, which could be arranged differently.

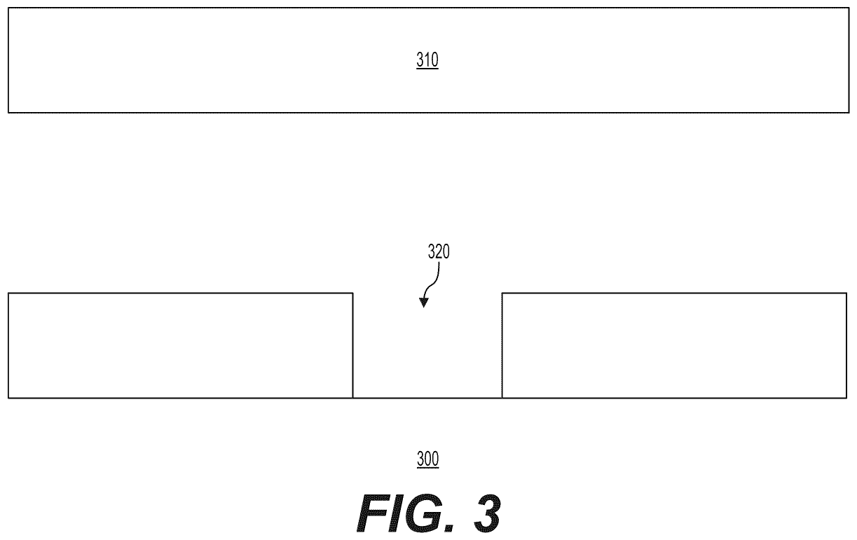

FIG. 3 shows a view 300 of two steps of the manufacturing process for forming back-to-back stacked silicon-based capacitors (e.g., back-to-back stacked silicon-based capacitors 232 and 234 of FIG. 2) as part of the core layer of FIG. 1 in accordance with one example. The top part of view 300 shows a portion of core layer 310 during the manufacturing process. As noted earlier, the core layer can comprise laminate materials that can be used to manufacture package substrates, including printed circuit boards. As an example, such materials include fiberglass-reinforced epoxy (e.g., referred to as FR-4 or FR-5). As shown in the bottom part of view 300, a slot 320 is formed in the portion of the core layer 310. Slot 320 is formed such that silicon-based capacitors can be formed. As part of this step of the manufacturing process, any number of such slots can be formed before forming the silicon-based capacitors.

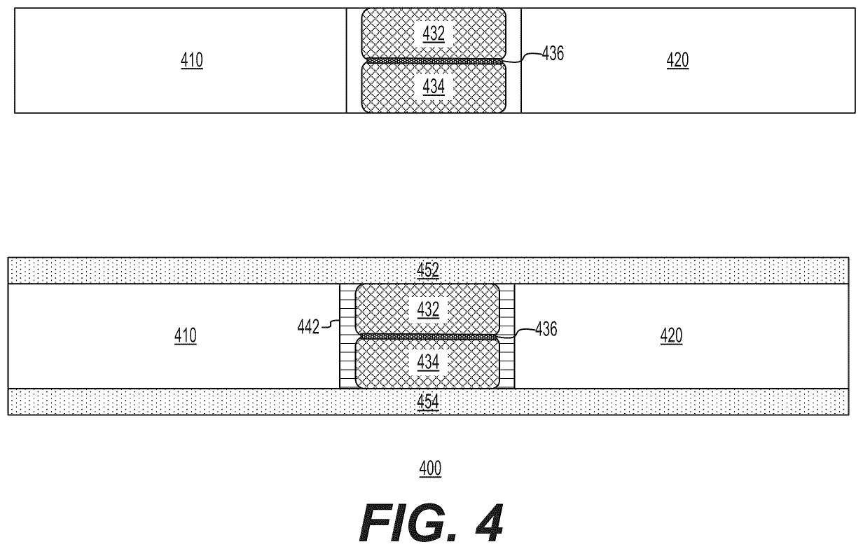

FIG. 4 shows a view 400 of the next steps of the manufacturing process for forming back-to-back stacked silicon-based capacitors as part of the core layer of FIG. 1 in accordance with one example. The top part of view 400 shows back-to-back stacked silicon-based capacitors 432 and 434 formed within a slot (e.g., slot 320 of view 300 of FIG. 3) separating a core layer portion 410 and another core layer portion 420. Back-to-back stacked silicon-based capacitors 432 and 434 are attached to each other using a bonding layer 436, as explained earlier with respect to FIG. 2. The bottom part of view 400 shows resin material 442 formed to plug any gaps between the back-to-back silicon-based capacitors 432 and 434 and core layer portion 410 and core layer portion 420, respectively. The bottom part of view 400 further shows build-up layers 452 and 454 formed. These layers are formed prior to the forming of build-up vias or other interconnect structures. In one example, build-up layers 452 and 454 may be formed using Ajinmoto build film (ABF) or similar materials. Although FIG. 4 shows a certain number of layers and components arranged in a certain manner there could be more or fewer number of layers or components, which could be arranged differently.

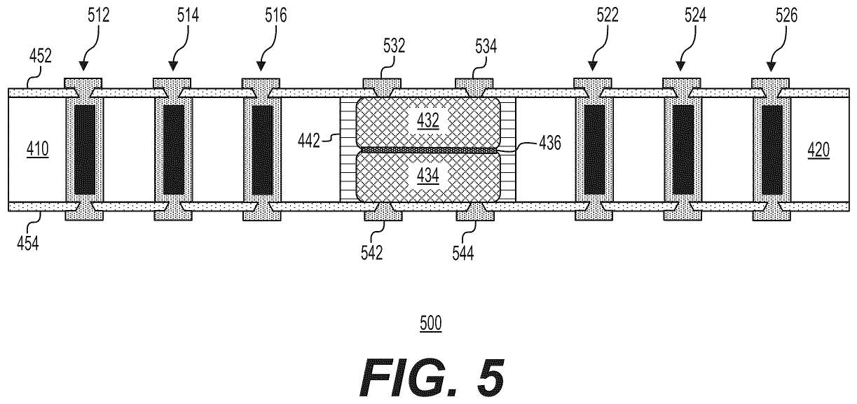

FIG. 5 shows a view 500 of the next steps of the manufacturing process for forming back-to-back stacked silicon-based capacitors as part of the core layer of FIG. 1 in accordance with one example. Unless labeled otherwise, view 500 uses the same reference numerals as used for FIG. 4 to identify the same, or portions of the same, structures or layers. Such structures or layers are not described again with respect to FIG. 5. View 500 shows build-up vias 532 and 534, which are associated with silicon-based capacitor 432. View 500 further shows build-up vias 542 and 544, which are associated with silicon-based capacitor 434.

As shown in view 500, plated-through holes and related build-up vias are formed in core layer portions 410 and 420. As an example, view 500 shows plated-through holes and associated build-up vias 512, 514, 516, 522, 524, and 526 formed in core layer portions 410 and 420. As shown in FIG. 5, the back-to-back stacked silicon-based capacitors 532 and 534 almost match the thickness of the core layer portions 410 and 420 without requiring a substantial amount of plugging resin. With this arrangement of these capacitors, the terminals for these capacitors are exposed to the upper and lower build-up layers of the package. In addition, the back-to-back stacked silicon-based capacitors 532 and 534 almost double the effective capacitance density. Although FIG. 5 shows a certain number of layers and components arranged in a certain manner there could be more or fewer number of layers or components, which could be arranged differently. In addition, the description of FIG. 5 refers to the new layers and structures shown as being formed as part of the next steps, some or all of the layers and structures could be formed as part of the previous steps shown in FIG. 4.

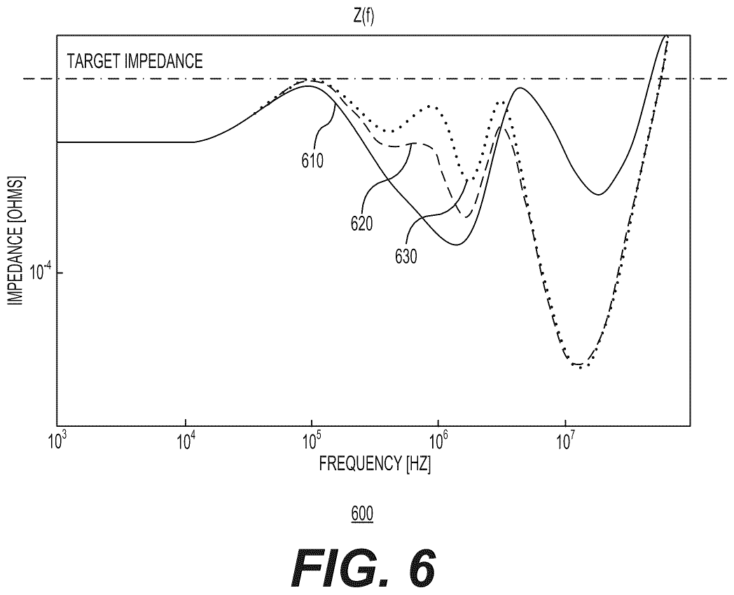

FIG. 6 shows curves 600 comparing the performance of power distribution networks (PDNs) with different capacitor designs included in a system. Each of the curves shown in FIG. 6 corresponds to a PDN with a certain arrangement of capacitors for use with a system including a package substrate having an SoC (e.g., system 100 of FIG. 1). Each curve plots the impedance of a respective power distribution network in relation to different frequency regions. These curves allow one to observe voltage fluctuations in relation to the dynamic changes in the workloads being executed by one or more processors incorporated as part of the SoC. One design goal for a system (e.g., system 100 of FIG. 1) is to keep the impedance below a certain threshold (e.g., the threshold indicated by the dotted line labeled as TARGET IMPEDANCE). This is because higher impedance requires a higher voltage supply (e.g., provided using a voltage regulator module associated with the system). The higher voltage supply, in turn, results in a higher power consumption by the system. Using the back-to-back silicon-based capacitors described herein the impedance can be managed in a manner that the system can perform with a reasonable power consumption regardless of the types of workloads being executed by the SoC. In other words, there are minimal large swings in the voltage being delivered by the PDN regardless of the fast changes in the power states of the SoC or other types of modules or circuits associated with the system.

Curve 610 corresponds to the impedance of a power distribution network with a single silicon-based capacitor and a certain amount of land-side capacitance (LSC). Curve 620 corresponds to the impedance of a power distribution network with back-to-back stacked silicon-based capacitors (e.g., as shown in FIG. 1 and FIG. 2) and a reduced amount of land-side capacitance (LSC) (e.g., half of the land-side capacitance compared to the PDN corresponding to curve 610). Curve 630 corresponds to the impedance of a power distribution network with back-to-back stacked silicon-based capacitors (e.g., as shown in FIG. 1 and FIG. 2) and a further reduced amount of land-side capacitance (LSC) (e.g., one-third of the land-side capacitance compared to the PDN corresponding to curve 610). Advantageously, as shown via the curves 620 and 630 in FIG. 6, one can use a smaller amount of land-side capacitance and still realize improved performance of the power distribution network in terms of the voltage fluctuations associated with dynamic changes in the workload. This, in turn, results in a greater amount of land-side resources being available for use with connections for packaging purposes. Furthermore, in certain configurations even the number of die-side capacitors can be reduced. In addition, by having the back-to-back stacked silicon-based capacitors, the core layer of the package substrate can accommodate a larger number of plated-through holes.

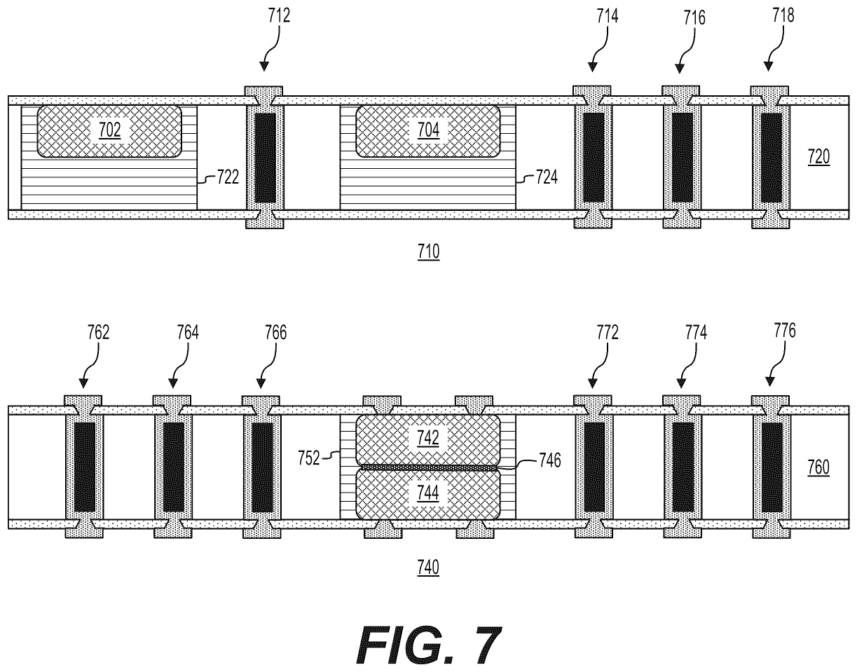

FIG. 7 shows a larger number of plated-through holes formed as part of a package substrate 740 with back-to-back stacked silicon-based capacitors relative to the number of plated-through holes formed as part of a package substrate 710 with non-stacked single capacitors. Package substrate 710 includes a non-stacked single capacitor 702 and another non-stacked single capacitor 704 in a core layer portion 720. Since the single capacitors take up only a portion of the core layer, the unoccupied part of the core layer is filled with plugging resin. As an example, pugging resin 722 is formed below and around the non-stacked single capacitor 702 and plugging resin 724 is formed below and around the non-stacked single capacitor 704. Package substrate 710 is also shown with plated-through holes and associated build-up vias 712, 714, 716, and 718 formed in core layer portion 720. Thus, in this example, there are only four plated-through holes in the core layer portion 720.

With continued reference to FIG. 7, package substrate 740 included back-to-back stacked silicon-based capacitors 742 and 744 formed within the core layer portion 760. Back-to-back stacked silicon-based capacitors 742 and 744 are attached to each other using a bonding layer 746. Plugging resin 752 is formed to fill-up any remaining area in a slot in which the silicon-based capacitors were placed. The back-to-back stacked silicon-based capacitors incorporated within package substrate 740 provide at least the same amount of capacitance as provided by the two non-stacked single capacitors incorporated within package substrate 710. However, the stacking of these capacitors frees up additional regions of the core layer portion 760, such that a larger number of plated-through holes can be accommodated within the same-sized region of the core layer portion 760. Thus, package substrate 740 is shown with plated-through holes and associated build-up vias 762, 764, 766, 772, 774, and 776 formed in core layer portion 760. Thus, in this example, there are six plated-through holes in the same-sized region of core layer portion 760 of package substrate 740 relative to the core layer portion 720 of package substrate 710. Thus, the use of back-to-back stacked silicon-based capacitors allows for the formation of a higher number of plated-through holes in a given region of the core layer. This is helpful because the plated-through holes can carry a larger amount of current compared with other types of packaging interconnects, allowing for higher power consumption without electrical issues.

In addition, in certain systems described herein, including the package substrate, there may be multiple voltage domains being served by the power distribution networks (PDNs). One example of a voltage domain relates to group of circuits or modules that are sharing the same power supply being provided via a voltage rail associated with the PDN. In such systems, one or more voltage domains may comprise modules (e.g., an SoC, another die, or a portion thereof) with a power dynamic including faster state changes relative to the modules in another voltage domain. In such systems, different voltage domains may be connected differently to the back-to-back stacked silicon-based capacitors. This is because the top capacitors from among the stacked capacitors may offer better performance than the bottom capacitors from among the stacked capacitors. As an example, the PDN, or a portion thereof, serving the voltage domain with a power dynamic including fast state changes may have connections to the top capacitors (e.g., back-to-back stacked silicon-based capacitor 742 of FIG. 7) from among the stacked capacitors. On the other hand, the PDN, or a portion thereof, serving a different voltage domain with a power dynamic including slow state changes may have connections to the bottom capacitors (e.g., back-to-back stacked silicon-based capacitor 742 of FIG. 7) from among the stacked capacitors. In systems, which have only one voltage domain, both stacked capacitors can be connected to the same voltage domain.

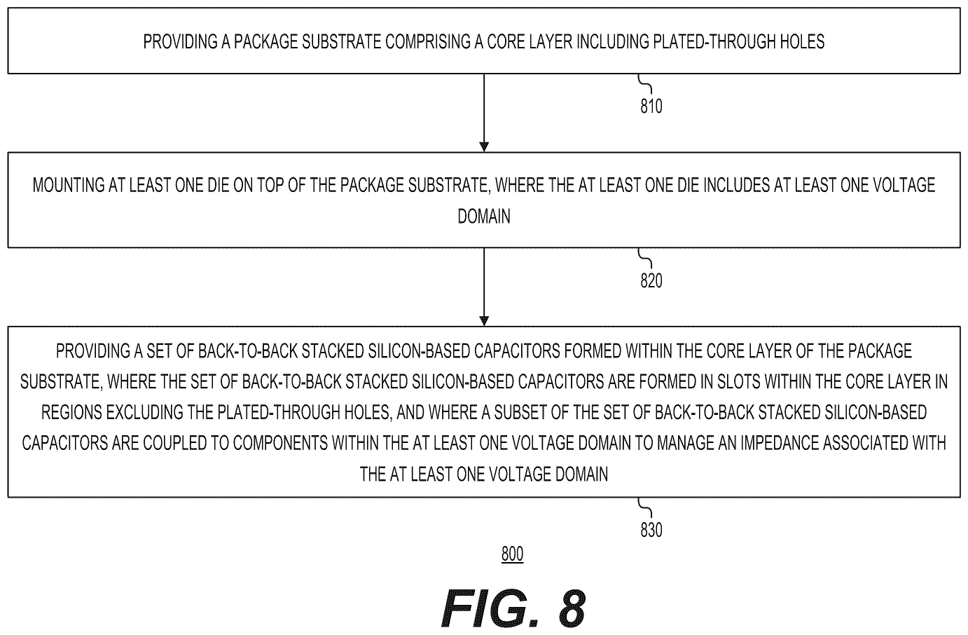

FIG. 8 shows a flow chart 800 of a method for providing a package substrate comprising back-to-back stacked silicon-based capacitors in accordance with one example. Step 810 includes providing a package substrate comprising a core layer including plated-through holes. In one example, this step relates to providing a package substrate (e.g., package substrate 110 of FIG. 1) where the package substrate includes a core layer (e.g., core layer 120 of FIG. 1) having plated-through holes (e.g., PTH 122 and 124 of FIG. 1). FIG. 2 shows an expanded view 200 of the core layer 120 of FIG. 1, including the silicon-based capacitors and certain build-up vias, which can act as terminals for the silicon-based capacitors.

Step 820 includes mounting at least one die on top of the package substrate, where the at least one die includes at least one voltage domain. As an example, the die mounted on top of the package substrate can be the SoC 190 described earlier. SoC 190 can include multiple voltage domains or other die mounted on top of package substrate can include additional voltage domains. As explained earlier, one example of a voltage domain relates to group of circuits or modules that are sharing the same power supply being provided via a voltage rail associated with the PDN. In such systems, one or more voltage domains may comprise modules (e.g., an SoC die, another die, or a portion thereof) with a power dynamic including faster state changes relative to the modules in another voltage domain.

With continued reference to FIG. 8, step 830 includes providing a set of back-to-back stacked silicon-based capacitors formed within the core layer of the package substrate, where the set of back-to-back stacked silicon-based capacitors are formed in slots within the core layer in regions excluding the plated-through holes, and where a subset of the set of back-to-back stacked silicon-based capacitors are coupled to components within the at least one voltage domain to manage an impedance associated with the at least one voltage domain. As explained earlier with respect to FIG. 1, back-to-back stacked silicon-based capacitors (e.g., silicon-based capacitors 152 and 156 of FIG. 1) can be provided as part of the core layer (e.g., core layer 120 of FIG. 1) in regions that do not include the plated-through holes (e.g., PTH 122 and 124 of FIG. 1). Through the build-up vias (e.g., any of the build-up vias 262, 264, 266, and 268 of FIG. 2), the silicon-based capacitors can be coupled to components (e.g., circuits or modules with SoC 190 of FIG. 1) within a voltage domain. As explained earlier with respect to FIG. 6, the silicon-based capacitors can be used to manage the impedance such that even fast state changes with respect to the power states, the impedance stays below a threshold.

In conclusion, the present disclosure relates to a system comprising a package substrate comprising a core layer including plated-through holes. The system may further include at least one die mounted on top of the package substrate, where the at least one die includes at least one voltage domain.

The system may further include a set of back-to-back stacked silicon-based capacitors formed within the core layer of the package substrate. The set of back-to-back stacked silicon-based capacitors may be formed in slots within the core layer in regions excluding the plated-through holes. A subset of the set of back-to-back stacked silicon-based capacitors may be coupled to components within the at least one voltage domain to manage an impedance associated with the at least one voltage domain.

Each of the set of back-to-back stacked silicon-based capacitors may comprise a first silicon-based capacitor stacked on top of a second silicon-based capacitor. The height of each of the set of back-to-back stacked silicon-based capacitors may be selected to be about the same as a width of the core layer.

The top surface of the package substrate corresponds to a die side, and a set of die-side capacitors may be mounted on the die side. The subset of the set of back-to-back silicon-based capacitors in conjunction with the set of die-side capacitors may help manage the impedance associated with the at least one voltage domain, thereby allowing a reduction in a number of the set of die-side capacitors, freeing up space on the die side of the package substrate.

The bottom surface of the package substrate corresponds to a land side, and a set of land-side capacitors may be mounted on the land side. The subset of the set of back-to-back silicon-based capacitors in conjunction with the set of land-side capacitors may help manage the impedance associated with the at least one voltage domain, thereby allowing a reduction in a number of the set of land-side capacitors, freeing up space on the land side of the package substrate.

In another example, the present disclosure relates to a system comprising a package substrate comprising a core layer including plated-through holes. The system may further include at least one die mounted on top of the package substrate, where the at least one die includes a first voltage domain and a second voltage domain, and where during operation of the system the first voltage domain requires faster changes in power than the second voltage domain.

The system may further include a set of back-to-back stacked silicon-based capacitors formed within the core layer of the package substrate. The set of back-to-back stacked silicon-based capacitors may be formed in slots within the core layer in regions excluding the plated-through holes. The set of back-to-back stacked silicon-based capacitors may comprise a first set of silicon-based capacitors stacked on a respective second set of silicon-based capacitors. The first set of the silicon-based capacitors are coupled to components within the first voltage domain, and where the second set of the silicon-based capacitors are coupled to components within the second voltage domain

The height of each of the set of back-to-back stacked silicon-based capacitors may be selected to be about the same as a width of the core layer. The top surface of the package substrate corresponds to a die side, and a set of die-side capacitors may be mounted on the die side. The set of back-to-back silicon-based capacitors in conjunction with the set of die-side capacitors may help manage an impedance associated with one or both of the first voltage domain and the second voltage domain, thereby allowing a reduction in a number of the set of die-side capacitors, freeing up space on the die side of the package substrate.

The bottom surface of the package substrate corresponds to a land side, and a set of land-side capacitors may be mounted on the land side. The set of back-to-back silicon-based capacitors in conjunction with the set of land-side capacitors may help manage an impedance associated with one or both of the first voltage domain and the second voltage domain, thereby allowing a reduction in a number of the set of land-side capacitors, freeing up space on the land side of the package substrate.

In yet another example, the present disclosure relates to a method comprising providing a package substrate comprising a core layer including plated-through holes. The method may further include mounting at least one die on top of the package substrate, where the at least die includes at least one voltage domain.

The method may further include providing a set of back-to-back stacked silicon-based capacitors formed within the core layer of the package substrate, where the set of back-to-back stacked silicon-based capacitors are formed in slots within the core layer in regions excluding the plated-through holes, and where a subset of the set of back-to-back stacked silicon-based capacitors are coupled to components within the at least one voltage domain to manage an impedance associated with the at least one voltage domain.

Each of the set of back-to-back stacked silicon-based capacitors may comprise a first silicon-based capacitor stacked on top of a second silicon-based capacitor. The method may further comprise selecting a height of each of the set of back-to-back stacked silicon-based capacitors to be about the same as a width of the core layer.

The top surface of the package substrate corresponds to a die side, and the method may further comprise mounting a set of die-side capacitors on the die side. The subset of the set of back-to-back silicon-based capacitors in conjunction with the set of die-side capacitors may help manage the impedance associated with the at least one voltage domain, thereby allowing a reduction in a number of the set of die-side capacitors, freeing up space on the die side of the package substrate.

The bottom surface of the package substrate corresponds to a land side, and the method may further comprise mounting a set of land-side capacitors on the land side. The subset of the set of back-to-back silicon-based capacitors in conjunction with the set of land-side capacitors may help manage the impedance associated with the at least one voltage domain, thereby allowing a reduction in a number of the set of land-side capacitors, freeing up space on the land side of the package substrate.

It is to be understood that the methods, modules, and components depicted herein are merely exemplary. Alternatively, or in addition, the functionality described herein can be performed, at least in part, by one or more hardware logic components. For example, and without limitation, illustrative types of hardware logic components that can be used include Field-Programmable Gate Arrays (FPGAs), Application-Specific Integrated Circuits (ASICs), Application-Specific Standard Products (ASSPs), and System-on-a-Chip systems (SoCs), Complex Programmable Logic Devices (CPLDs). In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or inter-medial components. Likewise, any two components so associated can also be viewed as being “operably connected,”or “coupled,” to each other to achieve the desired functionality.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the disclosure provides specific examples, various modifications and changes can be made without departing from the scope of the disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to a specific example are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a”or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed:

1. A system comprising:
a package substrate comprising a core layer including plated-through holes;
at least one die mounted on top of the package substrate, wherein the at least one die includes at least one voltage domain; and
a set of back-to-back stacked silicon-based capacitors formed within the core layer of the package substrate, wherein the set of back-to-back stacked silicon-based capacitors are formed in slots within the core layer in regions excluding the plated-through holes, and wherein a subset of the set of back-to-back stacked silicon-based capacitors are coupled to components within the at least one voltage domain to manage an impedance associated with the at least one voltage domain.

2. The system of claim 1, wherein each of the set of back-to-back stacked silicon-based capacitors comprises a first silicon-based capacitor stacked on top of a second silicon-based capacitor.

3. The system of claim 1, wherein a height of each of the set of back-to-back stacked silicon-based capacitors is selected to be about the same as a width of the core layer.

4. The system of claim 1, wherein the top surface of the package substrate corresponds to a die side, and wherein a set of die-side capacitors are mounted on the die side.

5. The system of claim 4, wherein the subset of the set of back-to-back silicon-based capacitors in conjunction with the set of die-side capacitors helps manage the impedance associated with the at least one voltage domain, thereby allowing a reduction in a number of the set of die-side capacitors, freeing up space on the die side of the package substrate.

6. The system of claim 1, wherein a bottom surface of the package substrate corresponds to a land side, and wherein a set of land-side capacitors are mounted on the land side.

7. The system of claim 6, wherein the subset of the set of back-to-back silicon-based capacitors in conjunction with the set of land-side capacitors helps manage the impedance associated with the at least one voltage domain, thereby allowing a reduction in a number of the set of land-side capacitors, freeing up space on the land side of the package substrate.

8. A system comprising:
a package substrate comprising a core layer including plated-through holes;
at least one die mounted on top of the package substrate, wherein the at least one die includes a first voltage domain and a second voltage domain, wherein during operation of the system the first voltage domain requires faster changes in power than the second voltage domain; and
a set of back-to-back stacked silicon-based capacitors formed within the core layer of the package substrate, wherein the set of back-to-back stacked silicon-based capacitors are formed in slots within the core layer in regions excluding the plated-through holes, wherein the set of back-to-back stacked silicon-based capacitors comprises a first set of silicon-based capacitors stacked on a respective second set of silicon-based capacitors, and wherein the first set of the silicon-based capacitors are coupled to components within the first voltage domain, and wherein the second set of the silicon-based capacitors are coupled to components within the second voltage domain.

9. The system of claim 8, wherein a height of each of the set of back-to-back stacked silicon-based capacitors is selected to be about the same as a width of the core layer.

10. The system of claim 8, wherein the top surface of the package substrate corresponds to a die side, and wherein a set of die-side capacitors are mounted on the die side.

11. The system of claim 10, wherein the set of back-to-back silicon-based capacitors in conjunction with the set of die-side capacitors helps manage an impedance associated with one or both of the first voltage domain and the second voltage domain, thereby allowing a reduction in a number of the set of die-side capacitors, freeing up space on the die side of the package substrate.

12. The system of claim 8, wherein a bottom surface of the package substrate corresponds to a land side, and wherein a set of land-side capacitors are mounted on the land side.

13. The system of claim 12, wherein the set of back-to-back silicon-based capacitors in conjunction with the set of land-side capacitors helps manage an impedance associated with one or both of the first voltage domain and the second voltage domain, thereby allowing a reduction in a number of the set of land-side capacitors, freeing up space on the land side of the package substrate.

14. A method comprising:
providing a package substrate comprising a core layer including plated-through holes;
mounting at least one die on top of the package substrate, wherein the at least one die includes at least one voltage domain; and
providing a set of back-to-back stacked silicon-based capacitors formed within the core layer of the package substrate, wherein the set of back-to-back stacked silicon-based capacitors are formed in slots within the core layer in regions excluding the plated-through holes, and wherein a subset of the set of back-to-back stacked silicon-based capacitors are coupled to components within the at least one voltage domain to manage an impedance associated with the at least one voltage domain.

15. The method of claim 14, wherein each of the set of back-to-back stacked silicon-based capacitors comprises a first silicon-based capacitor stacked on top of a second silicon-based capacitor.

16. The method of claim 15, further comprising selecting a height of each of the set of back-to-back stacked silicon-based capacitors to be about the same as a width of the core layer.

17. The method of claim 14, wherein a top surface of the package substrate corresponds to a die side, and the method further comprises mounting a set of die-side capacitors on the die side.

18. The method of claim 17, wherein the subset of the set of back-to-back silicon-based capacitors in conjunction with the set of die-side capacitors helps manage the impedance associated with the at least one voltage domain, thereby allowing a reduction in a number of the set of die-side capacitors, freeing up space on the die side of the package substrate.

19. The method of claim 14, wherein a bottom surface of the package substrate corresponds to a land side, and the method further comprises mounting a set of land-side capacitors on the land side.

20. The method of claim 19, wherein the subset of the set of back-to-back silicon-based capacitors in conjunction with the set of land-side capacitors helps manage the impedance associated with the at least one voltage domain, thereby allowing a reduction in a number of the set of land-side capacitors, freeing up space on the land side of the package substrate.
